(19) United States
(12) Patent Application Publication
(10) Pub. No.: US 2023/0387666 A1
(43) Pub. Date: Nov. 30, 2023

(54) INTEGRATED PHOTONIC APPARATUS AND METHOD

(71) Applicant: Xuan Sun, Rochester, NY (US)

(72) Inventor: Xuan Sun, Rochester, NY (US)

(21) Appl. No.: 18/321,086

(22) Filed: May 22, 2023

Related U.S. Application Data
(60) Provisional application No. 63/345,714, filed on May 25, 2022.

(51) Int. Cl. H01S 5/50; H01S 5/14; H01S 5/065; H01S 5/10; H01S 5/026; G02B 6/12

(52) U.S. Cl. CPC H01S 5/50; H01S 5/141; H01S 5/0657; H01S 5/1071; H01S 5/0265; G02B 6/12004; G02B 2006/12121; G02B 2006/1204

(57) ABSTRACT

A fully integrated photonic coherent microwave generator includes an external laser cavity on a suitable material waveguide platform (e.g., LiNbO3) operationally integrated with a III-V gain element. Operational components include a tunable high-Q resonator (e.g., LiNbO3 microresonator) and one or more end mirrors to form an integrated semiconductor external-cavity laser. Operationally coupled electrical components enable coherent microwave and phase-locked laser comb outputs as follows. An optical detector converts the beating of generated laser-comb modes into microwaves with a fundamental frequency equal to the free-spectral range f_{R} of the microresonator. The external laser cavity enables high-speed electro-optic modulation of laser modes directly inside the laser cavity. Phase locking of the lasing modes is accomplished via electro-optic modulation and electro-optic comb generation directly inside the laser cavity. Highly coherent microwaves are generated via phase-locked comb-like lasing modes.

### RELATED APPLICATION DATA

The instant application claims priority to U.S. Provisional application Ser. 63/345,714 filed May 25, 2022, the subject matter of which is herein incorporated by reference to the fullest extent allowed by applicable laws and rules.

### GOVERNMENT FUNDING

N/A

### Background

Aspects and embodiments most generally pertain to the field of integrated photonics, more particularly to an integrated photonic laser and microwave apparatus, methods, and applications, and most particularly to an integrated photonic coherent microwave generator, associated methods, and applications.

Spectrally pure microwaves are advantageous for many applications including but not limited to wireless communication, radar, imaging, clock, and high-speed electronics. Compared with electrical approaches, photonic technologies are superior for producing highly coherent microwaves given the high coherence of laser waves and given that optical division and optoelectronic down-conversion significantly suppress the phase noise. To date, a variety of photonic approaches have been developed for microwave generation; e.g., optoelectronic oscillator (OEO), dual-frequency laser, Brillouin laser, Kerr soliton micro-comb, and others known in the art. Optoelectronic oscillators rely on long, low-loss optical delay lines, which are challenging to implement on an integrated chip-scale platform. Although efforts have been reported for developing chip-scale OEOs, their performance is fairly poor compared with table-top counterparts. Microwaves produced via a dual-frequency laser generally exhibit significant phase noise, although their frequency can be widely tunable. Brillouin laser generation relies on an ultra-high-Q silica microdisk resonator or fiber laser, which are not fully integratable on a chip-scale platform. Kerr soliton microcombs can produce highly coherent microwaves that exhibit very low power efficiency.

The inventor has recognized that the related art problems outlined herein above may advantageously be remedied and known challenges mitigated by the enabled aspects and embodiments disclosed herein and as claimed. The apparatus and method disclosed herein enable the following advantageous benefits and improvements over current and past photonic microwave generation approaches. An external laser cavity enables high-speed electro-optic modulation of laser modes directly inside the laser cavity; phase locking of the lasing modes via electro-optic modulation and electro-optic comb generation directly inside the laser cavity; highly coherent microwave generation via phase-locked comb-like lasing modes; an electro-optic modulated III-V phase-locked comb laser fully integrated on a chip-scale platform.

### SUMMARY

An exemplary aspect is an electrooptic/photonic apparatus enabled to generate a coherent microwave output. The apparatus may be referred to herein as an integrated photonic coherent microwave generator. In an exemplary, non-limiting embodiment the integrated photonic coherent microwave generator includes an integrated external cavity laser that is formed by a high-Q resonator based external cavity on a suitable laser cavity material platform (including driving electrodes), integrated with a III-V gain element. The high-Q resonator laser cavity also includes one or more reflectors. The laser operationally produces a phase-locked laser comb output. Associated electronics are operationally coupled to the integrated photonic external cavity laser, wherein a coherent microwave output is operationally enabled by the apparatus.

In exemplary, non-limiting embodiments the III-V gain element may be edge coupled to the suitable laser cavity platform or heterogeneously integrated on/in a surface of the laser cavity platform. The associated electronics that are operationally coupled to the integrated photonic external cavity laser include an optical detector that converts the beating of laser modes into the RF/microwave regime via down-conversion, and a RF/microwave phase shifter enabling adjustment of the phase of the microwaves. In exemplary, non-limiting embodiments the integrated photonic coherent microwave generator may be comprised as follows and may include the disclosed components, elements, connections, features, implementations, and so on, alone or in various combinations as a PHOSITA would understand:
wherein the suitable high-Q resonator laser cavity material is one of electro-optic materials including lithium niobate (LiNbO3), GaAs, AlGaAs, InP, GaP, GaN, AlN, barium titanate (BaTiO3), KTP, potassium niobate (KNbO3), lithium tantalate (LiTaO3), or a composite medium formed by integrating one of these electro-optic materials with a dielectric material (such as silicon nitride and silicon diode), provided the external laser cavity can be modulated at a speed faster than the round-trip time of the resonator (and/or laser cavity) as a skilled person would understand.
wherein the high-Q resonator is a ring-shaped microresonator
wherein the high-Q resonator is a racetrack-shaped microresonator;
further including a phase modulator;
wherein the III-V gain element is a Reflective Semi-Conductor Optical Amplifier (RSOA) that is edge-coupled with the laser cavity material platform;
wherein the III-V gain element is heterogeneously integrated in/on a surface of the laser cavity material platform;
wherein the one or more cavity reflectors is a Sagnac loop mirror;
wherein the one or more cavity reflectors is a Bragg reflector;
further comprising an optical coupler;
   wherein the optical coupler is a 2×2 multimode interference (MMI) coupler;
wherein the high-Q resonator external cavity incorporates a phase modulator with driving electrodes without an incorporated high-Q microresonator;
wherein the associated electronics include a narrow-band RF/microwave filter;
wherein the associated electronics include a RF/microwave amplifier;
wherein the associated electronics are disposed on a separate platform from the external laser cavity platform.

An exemplary aspect is a method to generate a coherent microwave output on an integrated photonic platform. In an exemplary, non-limiting embodiment the method includes the steps of providing an integrated external cavity laser comprising a suitable material waveguide platform incorporating a high-Q microresonator characterized by a free-spectral range, f_{R}, and an integrated driving electrode and one or more cavity reflectors integrated with a III-V gain element, generating a multi-frequency comb-like laser output with a spectrum that matches the resonance frequencies of the high-Q microresonator, detecting the laser output and down-converting the beats of the lasing modes into a radio-frequency (RF) and/or microwave frequency regime having a comb-like spectrum with frequencies separated by n×f_{R} apart where n is an integer number n=1, 2, 3 . . . , feeding this RF/microwave signal back into the high-Q microresonator to electro-optically modulate the resonator and phase lock the laser modes, which produces a phase-locked laser comb that significantly enhances the coherence of the microwave output and supports regenerative microwave oscillation, and adjusting the phase of the feedback microwave so as to maximize the strength of mode locking by electro-optic modulation.

In an alternative exemplary, non-limiting embodiment the method includes the steps of providing the integrated high-Q laser cavity platform that incorporates a phase modulator with driving electrodes without an incorporated high-Q microresonator, and back-feeding the down-converted electrical signal to the phase modulator. In this case, the laser cavity itself functions as the high-Q resonator. Similarly to the description above, the integrated external-cavity laser produces comb-like lasing modes with frequency mode spacing f_{R} now equal to the free-spectral range of the laser cavity. Electro-optic modulation of the phase modulator with the detected microwave produces phase locking of the laser comb modes resulting in a phase-locked laser comb that in turn enhances the coherence of the produced microwave and supports regenerative microwave oscillation.

In exemplary, non-limiting embodiments the method may be comprised as follows and may include the disclosed steps, components, elements, connections, features, implementations, and so on, alone or in various combinations as a PHOSITA would understand:
further comprising providing the high-Q resonator waveguide platform as one of electro-optic materials including lithium niobate (LiNbO3), GaAs, AlGaAs, InP, GaP, GaN, AlN, barium titanate (BaTiO3), lithium tantalate (LiTaO3), KTP, potassium niobate (KNbO3), or a composite medium formed by integrating one of these electro-optic materials with a dielectric material such as silicon nitride or silicon dioxide, providing the external laser cavity is modulated at a speed faster than the round-trip time of the resonator (and/or laser cavity);
further comprising amplifying the power of the microwave output as necessary to support regenerative microwave oscillation;
further comprising filtering out broadband microwave noises (as well as the higher order harmonics if necessary) so as to increase the coherence and spectral purity of the microwave output.

### BRIEF DESCRIPTION OF THE DRAWINGS

FIG. 1 shows a perspective schematic of a photonic microwave generator according to an exemplary embodiment of the invention.

FIG. 2 shows a perspective schematic of a photonic microwave generator according to an exemplary embodiment of the invention.

FIG. 3 shows a perspective schematic of a photonic microwave generator according to an exemplary embodiment of the invention.

FIG. 4 shows a perspective schematic of a photonic microwave generator according to an exemplary embodiment of the invention.

FIG. 5 shows a perspective schematic of a photonic microwave generator according to an exemplary embodiment of the invention.

FIG. 6 shows a perspective schematic of a photonic microwave generator according to an exemplary embodiment of the invention.

FIG. 7 is a schematic showing the operation principle of a photonic microwave generator according to an exemplary embodiment of the invention.

FIG. 8 graphically shows a numerically simulated phase-locked laser comb spectrum according to an illustrative aspect of the invention.

FIGS. 9a, 9b graphically illustrate: a) an experimentally recorded optical spectrum of a phase-locked laser comb; and b) a corresponding RF spectrum of the microwave detected from the laser comb, according to illustrative aspects of the invention.

### DETAILED DESCRIPTION

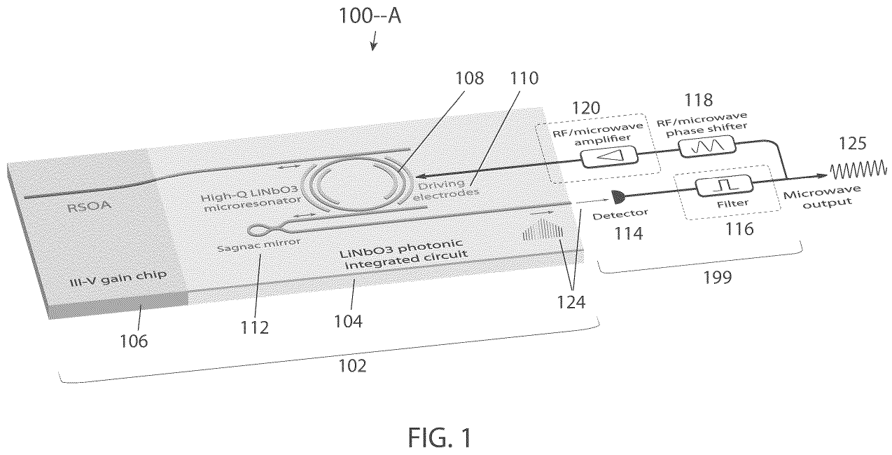

FIG. 1 shows a perspective schematic of a photonic coherent microwave generator 100-A according to an exemplary embodiment. A primary component of the microwave generator 100-A is an integrated semiconductor external-cavity laser 102 that is formed by a high-Q resonator-based external cavity on a suitable material platform 104 integrated with a III-V gain element 106. A suitable material for the high-Q external laser cavity platform includes but may not be limited to lithium niobate (LiNbO3), GaAs, AlGaAs, InP, GaP, GaN, AlN, barium titanate (BaTiO3), lithium tantalate (LiTaO3), KTP, potassium niobate (KNbO3), or a composite medium formed by integrating one of these electro-optic materials with a certain dielectric material such as silicon nitride or silicon dioxide; any of the materials being suitable providing the external laser can be modulated at a speed faster than the round-trip time of the resonator (and/or laser cavity), (equivalently, at a modulation bandwidth larger than the free-spectral range, f_{R}, of the laser cavity, advantageously (but not limited to) in the range of 0.1-100 GHz). Modulation of the laser cavity at a frequency equal to N×f_{R} where N is an integer N=1, 2, 3 . . . will phase lock the laser modes to produce a phase-locked comb laser, with a comb spectral bandwidth dependent on the group velocity dispersion of the resonator (and/or laser cavity). In addition, the group-velocity dispersion of the laser cavity can be engineered to enhance the comb spectrum and phase locking. For clarity of further descriptive aspects and embodiments the recited material will be lithium niobate (LiNbO3, “LN”) (however, again, aspects and embodiments are not limited as such).

A LN external cavity 102 includes a high-Q ring microresonator 108 characterized by a free spectral range f_{R}, that can be tuned and modulated by the electro-optic Pockels effect of LN, with tuning electrodes 110 integrated with the resonator. A Sagnac loop mirror 112 is placed at an output end of the resonator to function as the output end mirror of the laser cavity. Operationally, this novel laser will generate a phase-locked laser comb output 124.

The photonic coherent microwave generator 100-A further includes electrical components 199 operationally connected to the external cavity laser. The electrical components are used to detect the laser comb output from the integrated laser and down-convert it into the RF and/or microwave regime to produce a coherent microwave, which is fed back to electro-optically modulate the laser cavity to introduce and enhance phase locking of the lasing modes that in turn enhances the coherence of the generated microwave output. An optical detector 114 disposed at the laser output down-converts the beating of the phase-locked laser-comb modes into microwaves 125 having a fundamental frequency equal to the free-spectral range f_{R} of the LN ring microresonator 108. A RF/microwave phase shifter 118 is used to adjust the phase of the generated microwaves 125. Optionally, as shown in dotted box, a narrow-band RF/microwave filter 116 may be disposed optically downstream of the detector 114 to cut off broadband noises and pass only the fundamental frequency component at f_{R}. Optionally, as shown in dotted box, a RF/microwave amplifier 120 may be used as necessary to support regenerative microwave oscillation and boost the power of the generated microwave output 125.

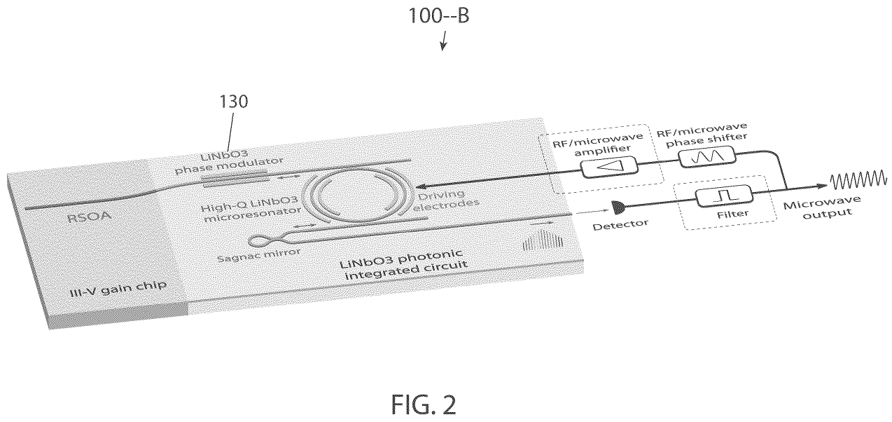

FIG. 2 shows a perspective schematic of a photonic microwave generator 100-B that is identical to the photonic microwave generator 100-A illustrated in FIG. 1 with the inclusion of a LN phase modulator 130 whose phase is tunable and/or modulated by the electro-optic Pockels effect of LN.

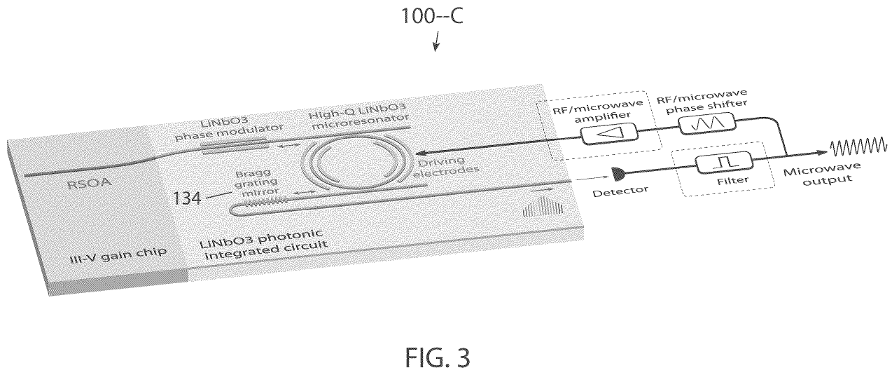

FIG. 3 shows a perspective schematic of a photonic microwave generator 100-C that is identical to the photonic microwave generator 100-B illustrated in FIG. 2 with the substitution of a Bragg reflector 134 cavity end mirror in place of the Sagnac loop mirror 112.

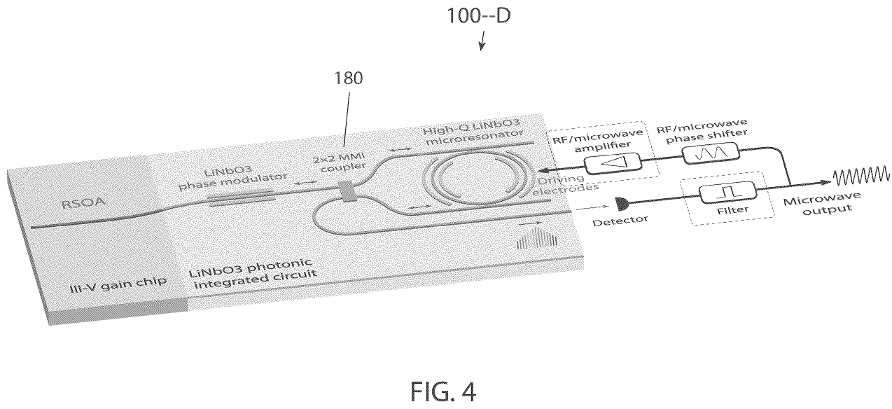

FIG. 4 shows another alternative device structure 100-D, where the Sagnac loop mirror is removed and the laser cavity is formed by the light feedback via a 2×2 coupler 180 (shown as a multimode interference (MMI) coupler). The laser light is coupled out of the laser cavity via the same 2×2 coupler. Other optical couplers well known in the art could be used in the alternative.

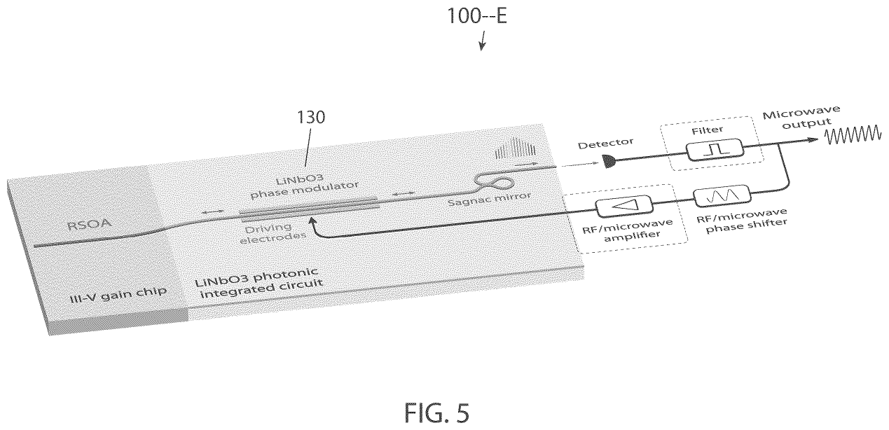

FIG. 5 shows another alternative structure 100-E, where the electro-optic microresonator is removed and the electrical signal is fed back to the LiNbO3 phase modulator 130. In this case, the whole III-V/LN laser cavity functions as a high-Q electro-optic resonator.

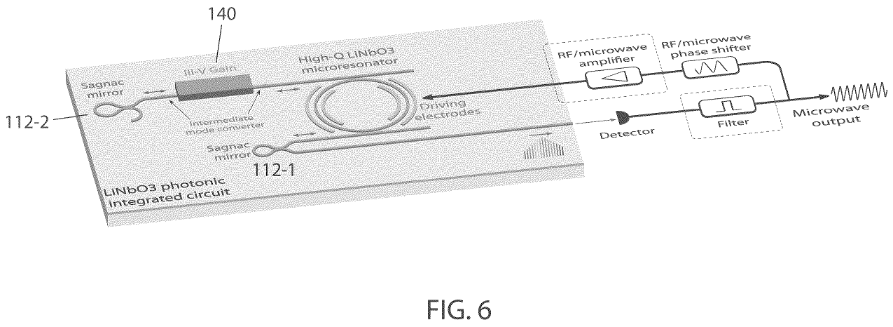

As illustrated in FIGS. 1-5, the III-V gain element 106 (shown as a reflective semiconductor optical amplifier (RSOA) is edge coupled to integrate with the external laser cavity. Alternatively, the III-V gain element can be heterogeneously integrated (at 140) in or on the surface of the LN platform as shown in FIG. 6. In this embodiment, two Sagnac loop mirrors 112-1, 112-2 function as resonator end reflectors.

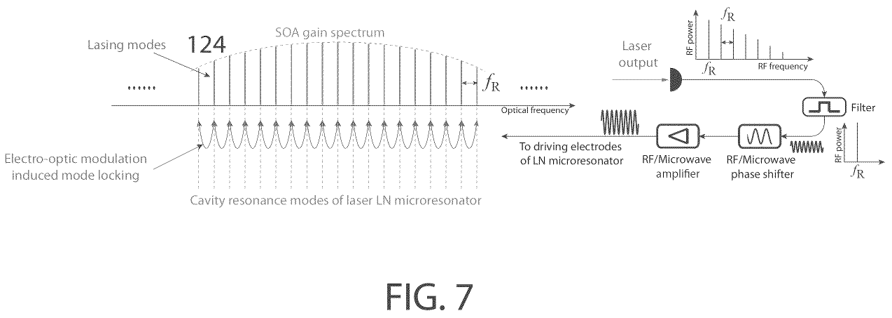

FIG. 7 illustrates the operation principle of an embodied photonic coherent microwave generator. The integrated III-V/LN laser lases at multiple frequencies 124 with a comb-like spectrum that matches the resonance frequencies of the LN ring microresonator with a free-spectral range of f_{R}. Optical detection of the multi-frequency laser output down-converts the laser beatings into the radio-frequency (RF) and/or microwave frequency regime, with a comb-like spectrum having frequencies separated by n×f_{R}, where n is an integer number n=1, 2, 3 . . . Feeding this RF/microwave signal back to the LN microresonator (FIGS. 1-4) or to the LiNbO3 phase modulator (FIG. 5) to electro-optically modulate the laser cavity introduces phase locking of the laser modes, which significantly enhances the coherence of the generated microwave. Moreover, the phase locking of the comb will produce periodic optical pulses in the time domain which in turn enhances the optical Kerr nonlinear effect inside the dispersion-engineered resonator (and/or inside the laser cavity) to produce more lasing modes via the cascaded four-wave mixing process, thus further broadening the comb spectrum. This effect can be significantly enhanced by appropriately matching the group delay of the whole laser cavity with that of the electro-optic microresonator. An electric phase shifter is employed to adjust the phase of the microwave so as to maximize the strength of mode locking by electro-optic modulation. A RF/microwave amplifier may advantageously be used to boost the power of the microwave so as to support regenerative microwave oscillation (the RF/microwave amplifier is optional if the microwave signal output from the optical detector is strong enough to support the regenerative microwave oscillation). A RF/microave filter is used to cut off broadband microwave noises (as well as the higher order harmonics if necessary) so as to increase the coherence and spectral purity of the microwave.

Experimental Verification

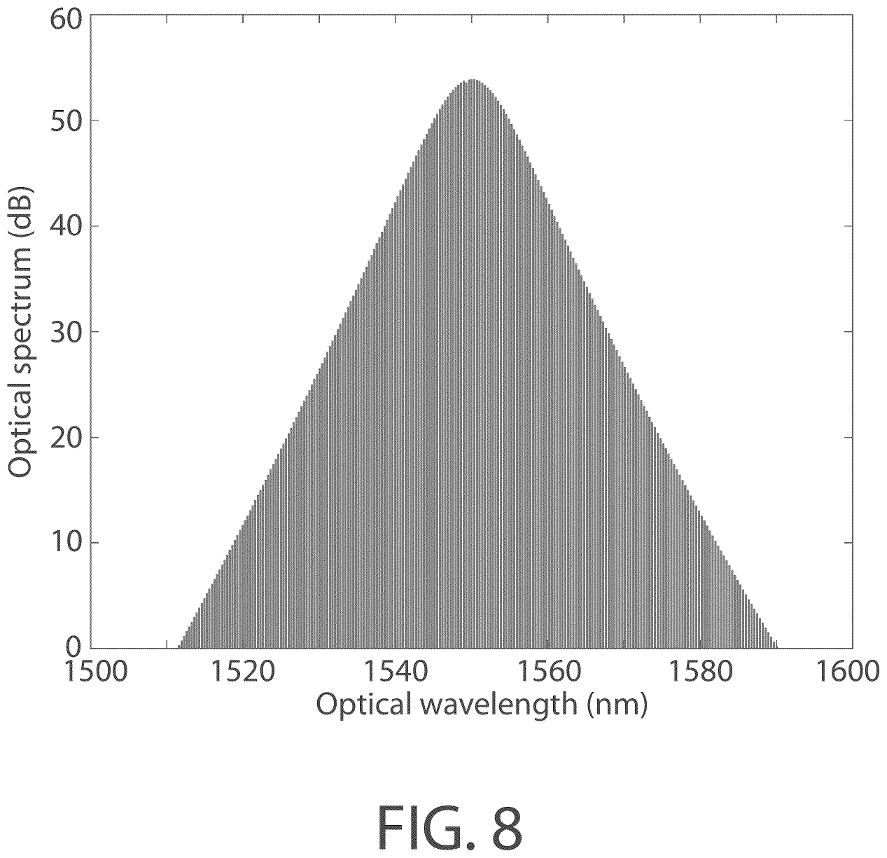

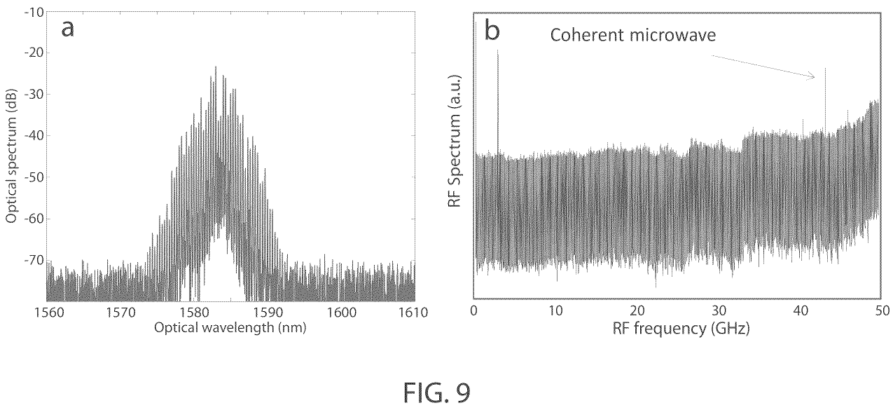

We have carried out numerical modeling via a modified Lugiato-Lefever equation by taking into account of the gain and laser actions. FIG. 8 shows an example of the numerically simulated result, which clearly shows the phase-locked optical comb state. We have also carried out preliminary experiments to verify the inventive concept. FIG. 9 shows some preliminary results. FIG. 9(a) shows the phase-locked laser comb spectrum and FIG. 9(b) shows clearly the detected coherent microwave around 42 GHz.

Among other benefits and advantages of the disclosed embodiments, the photonic coherent microwave generator and associated method exhibit significant novel characteristics not present in currently known photonic microwave and optical frequency comb generation approaches. These include, but are not limited to, high-speed electro-optic modulation of laser modes directly inside the laser cavity enabled by the LN external laser cavity; phase locking of the lasing modes via electro-optic modulation and electro-optic comb generation directly inside the laser cavity; spectral broadening of phase-locked comb via enhanced optical Kerr effect inside the microresonator (and/or the laser cavity); phase locking of the laser comb via combined electro-optic comb and optical Kerr comb generation; highly coherent microwave generation via phase-locked comb-like lasing modes; an electro-optic modulated III-V/LN phase-locked comb laser fully integrated on chip-scale platform, and others appreciated by those skilled in the art.

Notwithstanding that the numerical ranges and parameters setting forth the broad scope of the disclosed embodiments are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

While various disclosed embodiments have been described above, it should be understood that they have been presented by way of example only and not as a limitation. Numerous changes to the disclosed embodiments can be made in accordance with the specification herein without departing from the spirit or scope of this specification. Thus the breadth and scope of this specification should not be limited by any of the above-described embodiments; rather, the scope of this specification should be defined in accordance with the appended claims and their equivalents.

We claim:

1. An integrated photonic apparatus, comprising:
an integrated external cavity laser comprising a suitable material waveguide platform incorporating a high-Q resonator and an integrated driving electrode and at least one laser-cavity end reflector disposed in/on the platform and a laser gain element coupled thereto;
an optical detector operationally coupled to the integrated external cavity laser disposed to receive a laser output; and
a radio frequency (RF) and/or microwave phase shifter having an input operationally coupled to the optical detector and an output operationally coupled to the integrated laser platform.

2. The integrated photonic apparatus of claim 1, wherein the high-Q resonator is one of a photonic ring and a racetrack microresonator.

3. The integrated photonic apparatus of claim 2, further comprising a narrow-band RF/microwave filter disposed optically downstream of the detector.

4. The integrated photonic apparatus of claim 2, further comprising a RF/microwave amplifier having an output operationally coupled to the integrated laser platform.

5. The integrated photonic apparatus of claim 1, wherein the suitable material platform incorporating the high-Q resonator is one of lithium niobate (LiNbO3), GaAs, AlGaAs, InP, GaP, AlN, GaN, barium titanate (BaTiO3), lithium tantalate (LiTaO3), KTP, potassium niobate (KNbO3)), or a composite medium formed by integrating one of these materials with a dielectic material such as silicon nitride or silicon dioxide.

6. The integrated photonic apparatus of claim 2, wherein the at least one laser-cavity end reflector is a Sagnac mirror.

7. The integrated photonic apparatus of claim 2, wherein the at least one laser-cavity end reflector is a Bragg grating mirror.

8. The integrated photonic apparatus of claim 2, wherein the laser gain element is a III-V Reflective Semiconductor Optical Amplifier (RSOA).

9. The integrated photonic apparatus of claim 8, wherein the RSOA is edge coupled to the laser cavity platform.

10. The integrated photonic apparatus of claim 2, further comprising an integrated phase modulator adapted to electro-optically modulate the laser cavity.

11. The integrated photonic apparatus of claim 10, further comprising a narrow-band RF/microwave filter disposed optically downstream of the detector.

12. The integrated photonic apparatus of claim 10, further comprising a RF/microwave amplifier having an output operationally coupled to the integrated laser platform.

13. The integrated photonic apparatus of claim 10, wherein the suitable material platform incorporating the high-Q resonator is one of lithium niobate (LiNbO3), GaAs, AlGaAs, InP, GaP, AlN, GaN, barium titanate (BaTiO3), lithium tantalate (LiTaO3), KTP, potassium niobate (KNbO3), or a composite medium formed by integrating one of these materials with a dielectic material such as silicon nitride or silicon dioxide.

14. The integrated photonic apparatus of claim 10, wherein the high-Q resonator is one of a photonic ring and a racetrack microresonator.

15. The integrated photonic apparatus of claim 10, wherein the at least one laser-cavity end reflector is a Sagnac mirror.

16. The integrated photonic apparatus of claim 10, wherein the at least one laser-cavity end reflector is a Bragg grating mirror.

17. The integrated photonic apparatus of claim 10, wherein the laser gain element is a Reflective Semiconductor Optical Amplifier (RSOA).

18. The integrated photonic apparatus of claim 17, wherein the RSOA is edge coupled to the laser cavity platform.

19. The integrated photonic apparatus of claim 17, further comprising an optical coupler adapted to couple light into and out of the resonator and to couple the laser output to the detector.

20. The integrated photonic apparatus of claim 1, wherein the integrated external cavity laser consists of a phase modulator having an integrated driving electrode, a gain element, and at least one cavity end reflector.

21. The integrated photonic apparatus of claim 20, wherein the laser gain element is a Reflective Semiconductor Optical Amplifier (RSOA) that is edge coupled to the laser cavity platform.

22. The integrated photonic apparatus of claim 21, wherein the at least one cavity end reflector is a Sagnac mirror.

23. The integrated photonic apparatus of claim 20, further comprising a narrow-band RF/microwave filter disposed optically downstream of the detector.

24. The integrated photonic apparatus of claim 20, further comprising a RF/microwave amplifier having an output operationally coupled to the integrated laser platform.

25. The integrated photonic apparatus of claim 20, wherein the suitable material platform incorporating the high-Q resonator is one of lithium niobate (LiNbO3), GaAs, AlGaAs, InP, GaP, AlN, GaN, barium titanate (BaTiO3), lithium tantalate (LiTaO3), KTP, potassium niobate (KNbO3)), or a composite medium formed by integrating one of these materials with a dielectic material such as silicon nitride or silicon dioxide.

26. The integrated photonic apparatus of claim 2, wherein the laser gain element is a III-V gain element that is heterogeneously integrated in/on the waveguide platform, and further comprising a second cavity end reflector.

27. The integrated photonic apparatus of claim 26, wherein the second cavity end reflector is one of a Sagnac mirror and a Bragg grating mirror.

28. The integrated photonic apparatus of claim 1, wherein in operation the laser produces a phase-locked laser comb output and the optical detector detects multiple lasing frequencies of the phase-locked laser comb output and down-converts a beating of laser modes into the radio-frequency (RF) and/or microwave frequency regime.

29. A method for generating a coherent microwave, comprising:
providing an integrated external cavity laser comprising a suitable material waveguide platform incorporating a high-Q resonator characterized by a free-spectral range, f_{R}, and an integrated driving electrode and one or more cavity reflectors integrated with a III-V gain element;
generating a multi-frequency comb-like laser output with a spectrum that matches the resonance frequencies of the high-Q resonator;
detecting the laser output and down-converting the beats of the lasing modes into a radio-frequency (RF) and/or microwave frequency regime having a comb-like spectrum with frequencies separated by n×f_{R} apart where n is an integer number n=1, 2, 3 . . . ;
feeding the RF/microwave signal back into the high-Q resonator to electro-optically modulate the resonator and phase lock the laser modes; and
adjusting the phase of the feedback microwave so as to maximize the strength of mode locking by electro-optic modulation.

30. The method of claim 29, wherein the step of providing an integrated external cavity laser comprising a suitable material waveguide platform incorporating a high-Q resonator further comprises providing a high-Q microresonator.

31. The method of claim 29, further comprising amplifying the power of the microwave output as necessary to support regenerative microwave oscillation.

32. The method of claim 29, further comprising filtering out broadband microwave noises and higher order harmonics as necessary so as to increase the coherence and spectral purity of the microwave output.

33. The method of claim 29, further comprising providing the high-Q resonator waveguide platform as one of electro-optic materials including lithium niobate (LiNbO3), GaAs, AlGaAs, InP, GaP, AlN, GaN, barium titanate (BaTiO3), lithium tantalate (LiTaO3), KTP, potassium niobate (KNbO3), or a composite medium formed by integrating one of these electro-optic materials with a dielectric material such as silicon nitride or silicon dioxide.
